(19) United States
(12) Patent Application Publication
(10) Pub. No.: US 2009/0020414 A1
(43) Pub. Date: Jan. 22, 2009

(54) METHOD OF ELIMINATING ELECTROSTATIC CHARGES GENERATED FROM FRICTION BETWEEN A CARRIER AND A SUBSTRATE

(75) Inventors: Wen-Kuang Tsao, Taoyuan County (TW); Chien-Yu Chen, Taipei County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: CHUNGHWA PICTURE TUBES, LTD., Taoyuan (TW)

(21) Appl. No.: 12/234,699

(22) Filed: Sep. 21, 2008

Related U.S. Application Data
(63) Continuation of application No. 11/162,079, filed on Aug. 29, 2005.

(51) Int. Cl. C23C 14/34

(52) U.S. Cl. 204/192.1

(57) ABSTRACT

A method of eliminating electrostatic charges generated from friction between a carrier and a substrate is provided. A substrate having a front surface and a back surface is provided. A transparent conductive layer is formed on the back surface by sputtering or evaporation process, wherein the electrostatic charges accumulated on the carrier are eliminated through the transparent conductive layer when the anti-static substrate is in contact with the carrier.

### CROSS-REFERENCE TO RELATED APPLICATION

This application is a continuation application of a prior application Ser. No. 11/162,079, filed on Aug. 29, 2005. The entirety of each of the above-mentioned patent applications is hereby incorporated by reference herein and made a part of this specification.

### BACKGROUND OF THE INVENTION

1. Field of the Invention

The present invention generally relates to a method of eliminating electrostatic charges. More particularly, the present invention relates to method of eliminating electrostatic charges generated from friction between a carrier and a substrate.

2. Description of Related Art

Flat display panels are developed in recent years. Flat display panels are mainly divided into organic electro-luminescence displays (OELDs), plasma display panels (PDPs) and thin film transistor liquid crystal displays (TFT-LCDs). In a manufacturing procedure of the flat display panel, a plurality of devices are formed on a substrate through many processes. Therefore, the substrate should be transported or moved by a carrier in and out of many process chambers.

FIG. 1 shows a substrate for manufacturing a flat display panel. As shown in FIG. 1, the substrate 130 is an insulating glass substrate. Usually, when the substrate 130 is transported in a vacuum condition, electrostatic charges are generated on the substrate 130 owing to friction. Because the electrostatic charges are accumulated on the substrate 130, the devices on the substrate 130 may be damaged by electrostatic discharging. The detail description is as shown in FIG. 2A and FIG. 2B.

FIG. 2A and FIG. 2B are drawings showing a substrate that is transported by a carrier in the prior art. As shown in FIG. 2A, the carrier 100 includes two holding parts 110, two moving parts 120 and a robot arm 140. Each holding part 110 is fixed on each moving part 120 so as to carry the substrate 130 through the holding parts 110 and the moving parts 120. As shown in FIG. 2B, when the substrate 130 is carried near a process chamber (not shown), it will be held up by the robot arm 140 and be transported into the process chamber.

As shown in FIG. 2B, the substrate 130 and the carrier 100 repeatedly touch each other because the substrate 130 should be transported in and out of many process chambers. Thus, electrostatic charges 150 are generated owing to the friction between the substrate 130 and the carrier 100. The electrostatic charges 150 will be accumulated on the substrate 130 more and more as processes are performed on the substrate 130. The devices formed on the substrate 130 may be damaged by electrostatic discharging thereby the process yield is deteriorated.

### SUMMARY OF THE INVENTION

Accordingly, the present invention is directed to a method of eliminating electrostatic charges generated from friction between a carrier and a substrate anti-static substrate capable of preventing the substrate from electrostatic discharge damage and improving process yield.

A method of eliminating electrostatic charges generated from friction between a carrier and a substrate is provided. A substrate having a front surface and a back surface is provided. A transparent conductive layer is formed by sputtering or evaporation process on the back surface, wherein the electrostatic charges accumulated on the carrier are eliminated through the transparent conductive layer when the anti-static substrate is in contact with the carrier.

According to an embodiment of the present invention, said transparent conductive layer is selected from the group consisting of indium tin oxide, indium zinc oxide and a combination thereof.

According to an embodiment of the present invention, said substrate is a glass substrate, a quartz glass or a plastic substrate.

According to an embodiment of the present invention, the method further comprises forming a device layer on the front surface of the substrate.

In the present invention, the substrate has a conductive layer on its back surface so that electrostatic charges are not accumulated on the substrate. In other words, the conductive layer can prevent the substrate from electrostatic discharge damage so as to improve process yield.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a drawing showing a substrate for manufacturing a flat display panel in the prior art.

FIG. 2A and FIG. 2B are drawings showing a substrate that is transported by a carrier in the prior art.

FIG. 3 is a drawing showing an anti-static substrate according to an embodiment of the present invention.

FIG. 4 is a drawing showing the anti-static substrate of FIG. 3 held by the carrier.

FIG. 5 is a top view showing a front surface of the anti-static substrate according to an embodiment of the present invention.

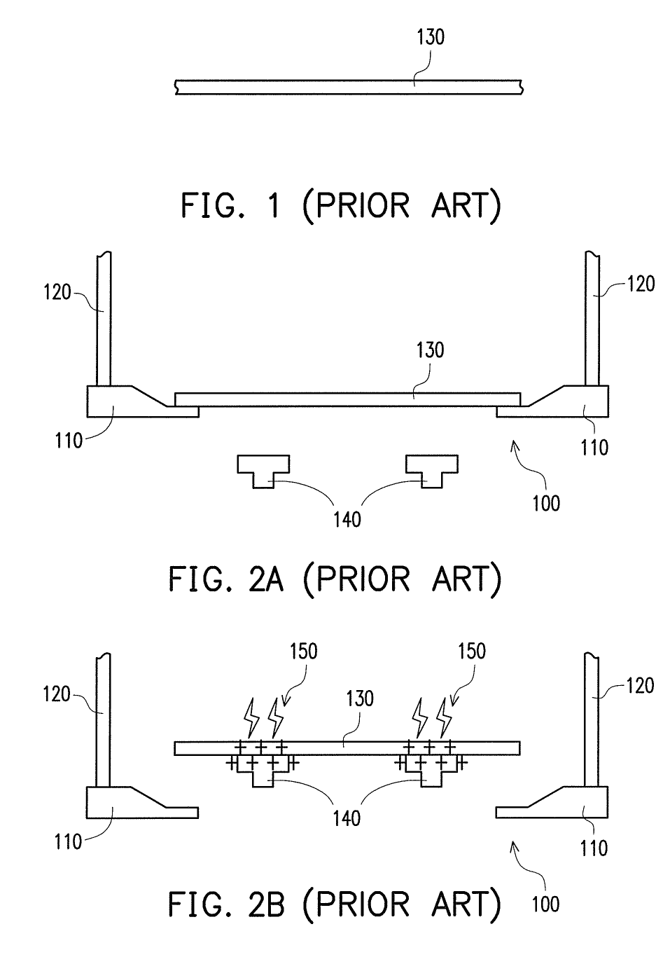

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

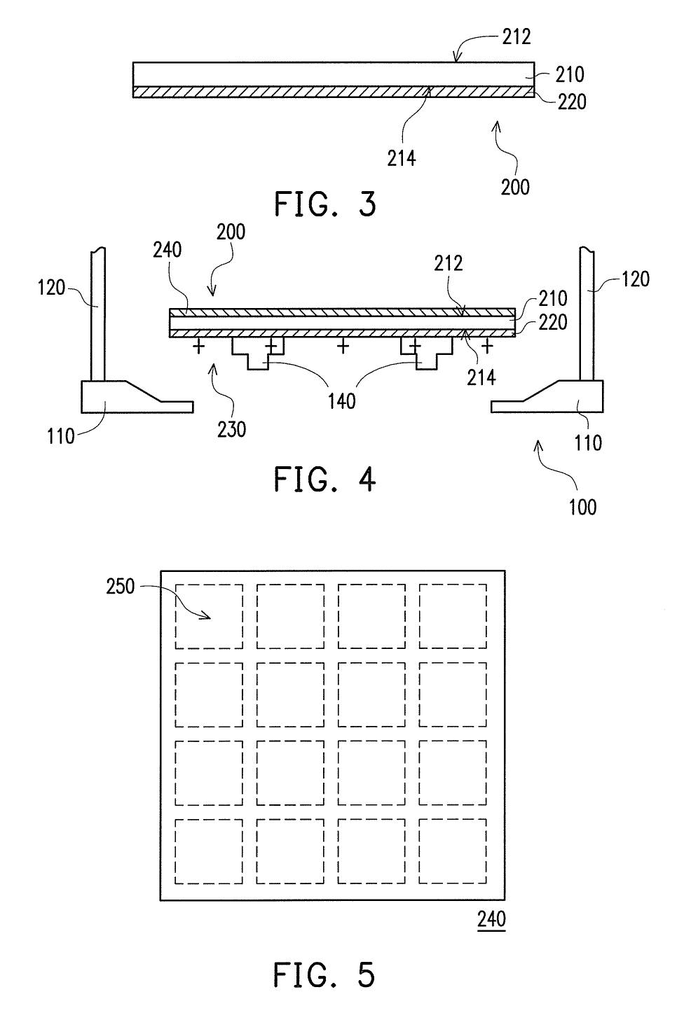

FIG. 3 is a drawing showing an anti-static substrate according to an embodiment of the present invention. FIG. 4 is a drawing showing the anti-static substrate of FIG. 3 held by the carrier. Please refer to FIG. 3 and FIG. 4, the anti-static substrate 200 is suitable for eliminating electrostatic charges 230 generated from the fraction between the anti-static substrate 200 and a carrier 100. The carrier 100 is the same or similar to the carrier 100 of FIG. 2A and FIG. 2B and is omitted herein. As shown in FIG. 3, the anti-static substrate 200 comprises a substrate 210 and a conductive layer 220. The substrate 210 has a front surface 212 and a back surface 214. The conductive layer 220 is disposed on the back surface of the substrate 210. As shown in FIG. 4, when the carrier 100 (the robot arm 140 of the carrier 100) is in contact with the conductive layer 220 on the back surface 214 of the substrate 210, the electrostatic charges 230 are not accumulated on the carrier 100 through the conductive layer 220. Therefore, the substrate 210 is not damaged from electrostatic discharging. In addition, if a device layer 240 has been formed on the front surface 212 of the substrate 210 after a plurality of processes are performed, the device layer 240 is not damaged from electrostatic discharging.

As shown in FIG. 3, the substrate 210 is a glass substrate, a quartz substrate or a plastic substrate, for example. The conductive layer 220 is a transparent conductive layer, for example. The transparent conductive layer is selected from the group consisting of indium tin oxide, indium zinc oxide and a combination thereof, for example. The conductive layer 220 is formed by sputtering process or evaporation process. The electrostatic charges 230 generated from the friction between the anti-static substrate 200 and the carrier 100 are not accumulated on the carrier 100 and/or the substrate 210 because of the formation of the conductive layer 220. Thus, the substrate 210 does not be damaged from electrostatic discharging. In addition, using the transparent conductive layer 220 for preventing electrostatic discharge damage has an advantage of that if the anti-static substrate 200 is used for manufacturing a liquid crystal display panel, a back surface light provided from a backlight module may pass through the transparent conductive layer 220 for displaying.

As shown in FIG. 4, according to another embodiment of the present invention, the anti-static substrate 200 further comprises a device layer 240 on the front surface 212 of the substrate 210. In other words, a device layer 240 may be formed on the front surface 212 of the substrate 210 after a plurality of processes are performed. FIG. 5 is a top view showing a front surface of the anti-static substrate according to an embodiment of the present invention. As shown in FIG. 5, the device layer 240 comprises a thin film transistor array 250 if the anti-static substrate 200 is used for manufacturing a liquid crystal display panel. The thin film transistor array 250 comprises a plurality of scan lines, a plurality of data lines and a plurality of thin film transistors electrically connected to the scan lines and the data lines, for example. Alternatively, the device layer 240 comprises an organic electroluminescence device array 250 if the anti-static substrate 200 is used for manufacturing an organic electroluminescence display. The organic electroluminescence device array 250 comprises a cathode layer, an organic emitting layer and an anode layer, for example. Alternatively, the device layer 240 comprises a device array 250 for a plasma display panel. The device array 250 comprises bus electrodes, sustain electrodes, for example. If the device layer 240 is formed on the front surface of the substrate 210, the device layer 240 does not be damaged from electrostatic discharging because a conductive layer 220 is formed on the back surface of the substrate 210. In other words, the electrostatic charges 230 generated from the friction between the carrier 100 and the anti-static substrate 200 are not accumulated because of the conductive layer 220. Therefore, the conductive layer 220 can prevent the device layer 240 from electrostatic discharge damage, and process yield can be improved.

Accordingly, because the anti-static substrate of the present invention has a conductive layer on its back surface, electrostatic charges generated from the friction between the carrier and the anti-static substrate are not accumulated. Hence, the device layer formed on the substrate does not damaged by electrostatic discharge, and process yield can be improved.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of eliminating electrostatic charges generated from friction between a carrier and a substrate, comprising:
providing a substrate having a front surface and a back surface; and
forming a transparent conductive layer by sputtering or evaporation process on the back surface, wherein the electrostatic charges accumulated on the carrier are eliminated through the transparent conductive layer when the substrate is in contact with the carrier.

2. The method according to claim 1, wherein the transparent conductive layer is selected from the group consisting of indium tin oxide, indium zinc oxide and a combination thereof.

3. The method according to claim 1, wherein the substrate is a glass substrate, a quartz glass or a plastic substrate.

4. The method according to claim 1, further comprising forming a device layer on the front surface of the substrate.

5. The method according to claim 4, wherein the device layer comprises a thin film transistor array.

6. The method according to claim 4, wherein the device layer comprises an organic electroluminescence device array.

7. The method according to claim 4, wherein the device layer comprises a device array for a plasma display panel.
